(19) United States
(12) Patent Application Publication
(10) Pub. No.: US 2022/0416077 A1
(43) Pub. Date: Dec. 29, 2022

(54) POWER SEMICONDUCTOR DIE WITH IMPROVED THERMAL PERFORMANCE

(71) Applicant: Wolfspeed, Inc., Durham, NC (US)

(72) Inventor: Ty Richard McNutt, Farmington, AR (US)

(21) Appl. No.: 17/357,103

(22) Filed: Jun. 24, 2021

(51) Int. Cl. H01L 29/78; H01L 29/06

(52) U.S. Cl. CPC H01L 29/7811; H01L 29/0684; H01L 29/1608

(57) ABSTRACT

A power semiconductor die includes a substrate and a drift layer on the substrate. The drift layer includes an active area, an edge termination area surrounding the active area, and a thermal dissipation area surrounding the edge termination area. The thermal dissipation area is configured to reduce a thermal resistance of the power semiconductor die. By providing the thermal dissipation area, the operating voltage and/or current of the power semiconductor die can be increased without an increase in the active area. Further, the manufacturing yield of the power semiconductor die can be improved.

### FIELD OF THE DISCLOSURE

The present disclosure is related to power semiconductor devices, and in particular to power semiconductor die having improved thermal performance.

### BACKGROUND

Power semiconductor die provide power devices that are used to selectively deliver power to a load. For example, a power semiconductor die may provide a metal-oxide-semiconductor field-effect transistor (MOSFET), an insulated gate bipolar transistor (IGBT), a diode, or the like. Wide bandgap (e.g., silicon carbide) power semiconductor die have become popular in recent times due to their superior performance when compared to their conventional (e.g., silicon) counterparts. For example, wide bandgap semiconductor die can generally support higher voltages and power densities. However, there are several challenges associated with designing and producing power semiconductor die utilizing wide bandgap material systems. In particular, due to their high power density, power semiconductor die utilizing wide bandgap material systems may have issues with heat dissipation. Further, power semiconductor die utilizing wide bandgap material systems may provide relatively low yield in production.

Power semiconductor die may be coupled together including basic support circuitry to provide a power module. During operation in a system environment, the voltage and current at which the power module is operated is dictated by the thermal performance of the power semiconductor die therein. In many cases, the power semiconductor die may be required to be operated at a voltage and/or current lower than what the power semiconductor die is rated due to thermal performance issues. Accordingly, there is a need for power semiconductor die having improved thermal performance and yield.

### SUMMARY

In one embodiment, a power semiconductor die includes a substrate and a drift layer on the substrate. The drift layer includes an active area, an edge termination area surrounding the active area, and a thermal dissipation area surrounding the edge termination area. The thermal dissipation area is configured to reduce a thermal resistance of the power semiconductor die. By providing the thermal dissipation area, the operating voltage and/or current of the power semiconductor die can be increased without an increase in the active area. The lack of increase in the active area contributes to an improvement in the manufacturing yield of the power semiconductor die compared to a device that increases the active area alone to get lower on state resistance and/or more thermal dissipation area. When adding non-active area for thermal dissipation, the yield of the semiconductor device can approach the yield of a smaller active area device while simultaneously having the thermal performance of a larger active area device. In other words, the thermal dissipation area provides a better tradeoff between yield and performance than was previously achievable by increasing the active area alone.

In one embodiment, the active area includes one or more implanted regions, and is configured to conduct current during a conduction mode of operation of the power semiconductor die. The edge termination area includes one or more implanted termination regions, and is configured to reduce an electric field during a blocking mode of operation of the power semiconductor die. The thermal dissipation area does not play a role in the electrical operation of the power semiconductor die.

In one embodiment, the thermal dissipation area does not include any implanted regions. A ratio of the combination of the active area and the edge termination area to the combination of the active area, the edge termination area, and the thermal dissipation area may be between 1:1.10 and 1:1.35. The thermal dissipation area may comprise at least 10% of a total area of the power semiconductor die, and up to 35% of the total area of the power semiconductor die. In one embodiment, a blocking voltage of the power semiconductor die is less than 10 kV, and in various embodiments may be less than 9 kV, less than 8 kV, less than 7 kV, and less than 6.5 kV. The substrate and the drift layer may comprise a wide bandgap semiconductor material, which may be silicon carbide in some embodiments. The one or more implanted regions in the active area may provide a metal-oxide-semiconductor field-effect transistor (MOSFET).

In one embodiment, a power semiconductor die includes a substrate and a drift layer on the substrate. The drift layer includes an active area and an edge termination area. The active area and the edge termination area comprise less than 90% of a total area of the power semiconductor die, and as low as 65% of the total area of the power semiconductor die. By limiting the area of the active area and the edge termination area, the thermal resistance of the power semiconductor die may be improved. Further, the manufacturing yield of the power semiconductor die may be improved.

In one embodiment, the active area includes one or more implanted regions, and is configured to conduct current during a conduction mode of operation of the power semiconductor die. The edge termination area includes one or more implanted termination regions, and is configured to reduce an electric field during a blocking mode of operation of the power semiconductor die.

The substrate and the drift layer may comprise a wide bandgap semiconductor material, such as silicon carbide. A blocking voltage of the power semiconductor die may be less than 10 kV, and in various embodiments may be less than 9 kV, less than 8 kV, less than 7 kV, and less than 6.5 kV. The one or more implanted regions in the active area may provide a MOSFET.

In one embodiment, a power module includes a power substrate and one or more power semiconductor die on the power substrate. Each of the power semiconductor die include a substrate and a drift layer on the substrate. The drift layer includes an active area, an edge termination area surrounding the active area, and a thermal dissipation area surrounding the edge termination area. The edge termination area is configured to reduce a thermal resistance of the power semiconductor die. By providing the thermal dissipation area, the operating voltage and/or current of the power semiconductor die can be increased without an increase in on-state resistance. Further, the manufacturing yield of the power semiconductor die can be improved.

In one embodiment, the active area includes one or more implanted regions, and is configured to conduct current during a conduction mode of operation of the power semiconductor die. The edge termination area includes one or more implanted termination regions, and is configured to reduce an electric field during a blocking mode of operation of the power semiconductor die. The thermal dissipation area does not play a role in the electrical operation of the power semiconductor die.

In one embodiment, the thermal dissipation area does not include any implanted regions. A ratio of the combination of the active area and the edge termination area to the combination of the active area, the edge termination area, and the thermal dissipation area may be between 1:1.10 and 1:1.35. The thermal dissipation area may comprise at least 10% of a total area of the power semiconductor die, and up to 35% of the total area of the power semiconductor die. In one embodiment, a blocking voltage of the power semiconductor die is less than 10 kV, and in various embodiments may be less than 9 kV, less than 8 kV, less than 7 kV, and less than 6.5 kV. The substrate and the drift layer may comprise a wide bandgap semiconductor material, which may be silicon carbide in some embodiments. The one or more implanted regions in the active area may provide a metal-oxide-semiconductor field-effect transistor (MOSFET).

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A and 1B illustrate a power semiconductor die according to one embodiment of the present disclosure.

FIGS. 2A and 2B illustrate a power semiconductor die according to one embodiment of the present disclosure.

FIG. 3 is a graph illustrating a relationship between chip area and manufacturing yield according to one embodiment of the present disclosure.

FIG. 4 illustrates a power module according to one embodiment of the present disclosure.

FIG. 5 illustrates a cross-sectional view of a power semiconductor die in a power module according to one embodiment of the present disclosure.

FIG. 6 illustrates a metal-oxide-semiconductor field-effect transistor (MOSFET) cell according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

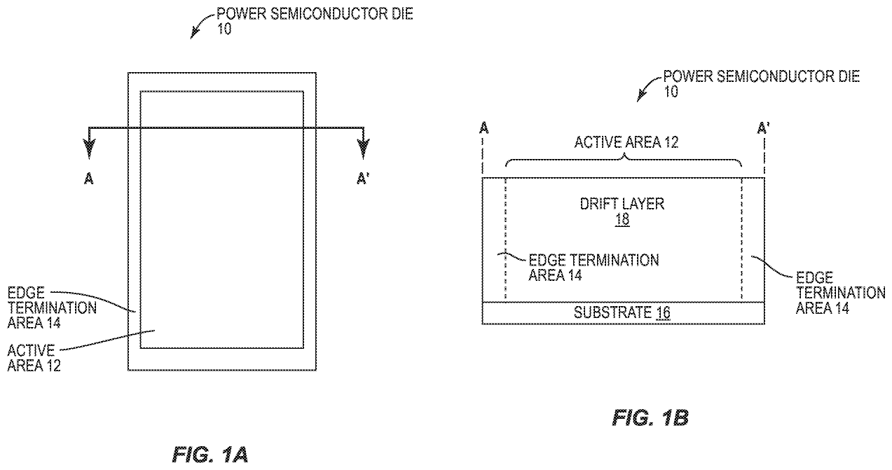

FIG. 1A shows a top-down view of a power semiconductor die 10 according to one embodiment of the present disclosure. The power semiconductor die 10 includes an active area 12 and an edge termination area 14 surrounding the active area 12. The active area 12 is the area in which one or more implanted regions are located to provide the functionality of the device, which includes selectively conducting current between a first contact and a second contact. The edge termination area 14 is the area in which one or more implanted termination regions are located to reduce or terminate an electric field during a blocking mode of operation. The edge termination area 14 can comprise one or more implanted regions (e.g., guard rings, junction termination extensions (JTEs), a combination of guard rings and JTEs, field stop implants, or the like) and non-implanted regions (often depleting in operation) between implanted regions to support the electric field at the device edges or corners. Notably, the electric field is terminated at the end of the edge termination area 14, such that if any non-active area outside of the edge termination region 14 were damaged or not printed, the electrical functionality of the power semiconductor die 10 would be unaffected.

FIG. 1B shows a cross-sectional view through line A-A′ of the power semiconductor die 10. The power semiconductor die 10 includes a substrate 16 and a drift layer 18 on the substrate 16. The drift layer 18 is separated into the active area 12, which is surrounded by the edge termination area 14.

Since the active area 12 provides the functionality of the power semiconductor die 10, because the size of the active area 12 is proportional to an on-state resistance R_{dSON} of the power semiconductor die 10, and because wide bandgap materials are generally expensive, conventional design rules dictate maximizing the ratio of the active area 12 to the total area of the power semiconductor die 10 and minimizing the total area of the power semiconductor die 10. As shown in FIGS. 1A and 1B, the combination of the active area 12 and the edge termination area 14 makes up nearly 100% of the total area of the power semiconductor die 10. Designing power semiconductor die 10 in this way may have several undesirable consequences.

First, maximizing the active area 12 and minimizing the total area of the power semiconductor die 10 may result in reduced manufacturing yield for the power semiconductor die 10. Since practically the entirety of the power semiconductor 10 serves a functional purpose, with the active area 12 providing the selective conduction functionality and the edge termination area 14 providing electric field termination, both of which are critical to the electrical operation of the power semiconductor die 10, there is little room for manufacturing defects that do not interfere with the operation of the device. Accordingly, power semiconductor die 10 including a small number of defects will be rendered inoperable, thus decreasing the manufacturing yield. Second, the compact design results in high power density and thus high operating temperatures. When the power semiconductor die 10 is provided in a power module, limits on thermal dissipation may require throttling the voltage and/or current handled by the power semiconductor die 10, operating at a voltage and/or current less than the power semiconductor die 10 is capable due to thermal constraints.

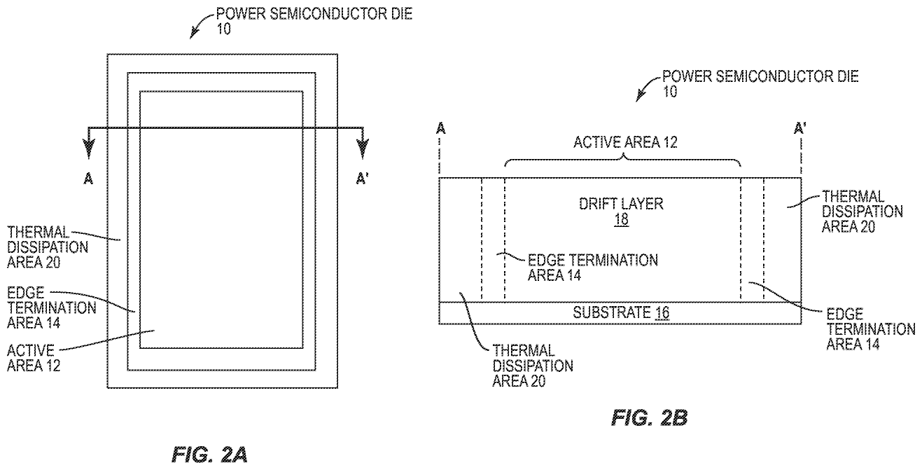

In an effort to improve manufacturing yield and thermal performance of the power semiconductor die 10, FIG. 2A shows a top-down view of the power semiconductor die 10 according to one embodiment of the present disclosure. FIG. 2B shows a cross-sectional view of the power semiconductor die 10 through line A-A′. As shown, the power semiconductor die 10 includes the active area 12 and the edge termination area 14 surrounding the active area 12. The power semiconductor die 10 further includes a thermal dissipation area 20 surrounding the edge termination area 14. The thermal dissipation area 20 does not play a role in the electrical operation of the power semiconductor die 10. Rather, the thermal dissipation area 20 is provided to decrease a thermal resistance of the power semiconductor die 10.

In various embodiments, a ratio of the combination of the active area 12 and the edge termination area 14 to the combination of the active area 12, the edge termination area 14, and the thermal dissipation area 20 is between 1:1.10 and 1:1.35. In various embodiments, the ratio of the combination of the active area 12 and the edge termination area 14 to the combination of the active area 12, the edge termination area 14, and the thermal dissipation area 20 can be within any subrange or discrete point within the broader range 1:1.10 and 1:1.35. For example, the ratio of the combination of the active area 12 and the edge termination area 14 to the thermal dissipation area 20 may be between 1:1.10 and 1:1.15, between 1:1.10 and 1:1.20, between 1:1.10 and 1:1.25, between 1:1.10 and 1:1.30, between 1:1.15 and 1:1.35, between 1:1.20 and 1:1.35, between 1:1.25 and 1:1.35, between 1:1.30 and 1:1.35, between 1:1.15 and 1:1.30, between 1:1.20 and 1:30, between 1:1.25 and 1:1.30, between 1:1.15 and 1:1.25, between 1:1.20 and 1:1.25, and between 1:1.15 and 1:1.20, or at any discrete point. The thermal dissipation area 20 may comprise at least 10% of the total area of the power semiconductor die 10, and up to 35% of the total area of the power semiconductor die 10, while the combination of the active area 12 and the edge termination area 14 comprises less than 90% of the total area of the power semiconductor die 10, and as low as 65% of the total area of the power semiconductor die 10. In various embodiments, the thermal dissipation area 20 may comprise any subrange or discrete point within the broader range of 10% to 35% of the total area of the power semiconductor die 10. For example, the thermal dissipation area 20 may comprise between 10% and 30%, between 10% and 25%, between 10% and 20%, between 10% and 15%, between 15% and 35%, between 20% and 35%, between 25% and 35%, between 30% and 35%, between 15% and 30%, between 20% and 30%, between 25% and 30%, between 15% and 25%, between 20% and 25%, and between 15% to 20% of the total area of the power semiconductor die 10, or any discrete point therein. The thermal dissipation area 20 may contain no implanted regions, such that it is an “empty” part of the drift layer 18. However, in some embodiments one or more implanted, diffused, or otherwise doped regions may be provided in order to improve a thermal performance thereof. In such embodiments, the thermal dissipation area 20 is nonetheless electrically inactive, wherein electrically inactive is defined herein as not playing a role in the electrical operation of the power semiconductor die 10 when thermal performance of the die is not taken into consideration. In other words, the thermal dissipation area 20 only plays a role in the electrical operation of the power semiconductor die 10 insofar as it affects the thermal dissipation thereof.

The substrate 16 and the drift layer 18 may comprise a wide bandgap material (e.g., a material having a bandgap greater than 2 eV). For example, the substrate 16 and the drift layer 18 may comprise silicon carbide. Implanted regions in the active area 12 may provide any number of power semiconductor devices such as a metal-oxide-semiconductor field-effect transistor (MOSFET), an insulated gate bipolar transistor (IGBT), a diode, and the like.

The addition of the thermal dissipation area 20 provides two main benefits. First the, thermal dissipation area 20 increases manufacturing yield compared to the same total area device having a larger portion of the total area dedicated to active area and/or edge termination area. Since the thermal dissipation area 20 does not participate in the electrical operation of the power semiconductor die 10, defects can be present in the thermal dissipation area 20 without rendering the power semiconductor die 10 inoperable. As discussed above, wide bandgap materials are expensive, and thus conventional design rules have dictated minimizing the total area of the power semiconductor die 10. While the thermal dissipation area 20 will increase the cost of the power semiconductor die 10 due to the increased amount of material used, this may be partially or completely offset by the improvements in manufacturing yield.

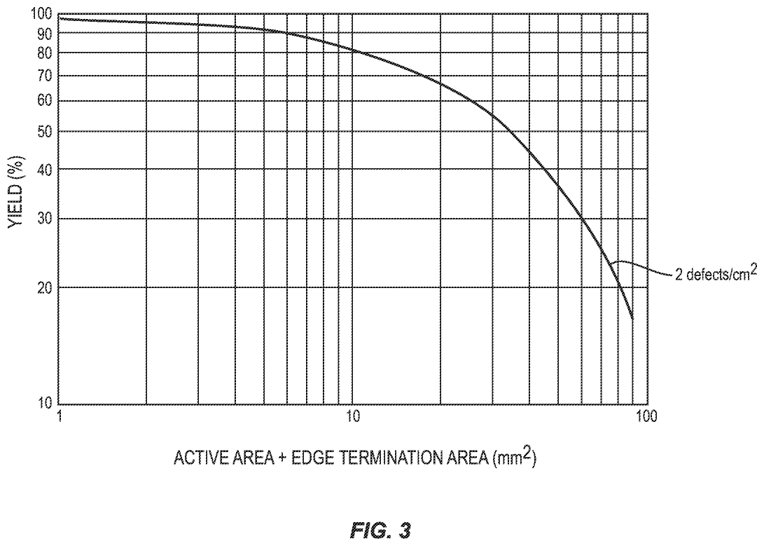

To illustrate this benefit, FIG. 3 is a graph showing a relationship between chip area, which is the combined active area 12 and edge termination area 14, and yield. The graph shows the relationship between chip area and yield for an average of 2 defects per square centimeter. As shown, the yield for a semiconductor die decreases as the chip area increases, dropping off in an exponential fashion. By adding in the thermal dissipation area 20, the power semiconductor die 10 can have the thermal benefits of a larger device (thereby allowing for more voltage and/or current) while moving up on the yield curve shown due to the reduced active chip area.

Second, the thermal dissipation area 20 decreases thermal resistance of the power semiconductor die 10, which may allow the power semiconductor die 10 to be operated at higher voltages and/or currents when used in a power module. Since the size of the active area 12 is not increased, the on-state resistance R_{dSON} of the power semiconductor die 10 remains at the same low value as in FIGS. 1A and 1B above, but with improved thermal performance. Accordingly, the thermal dissipation area 20 may provide a better tradeoff between on-state resistance R_{dSON} and thermal resistance than was previously possible.

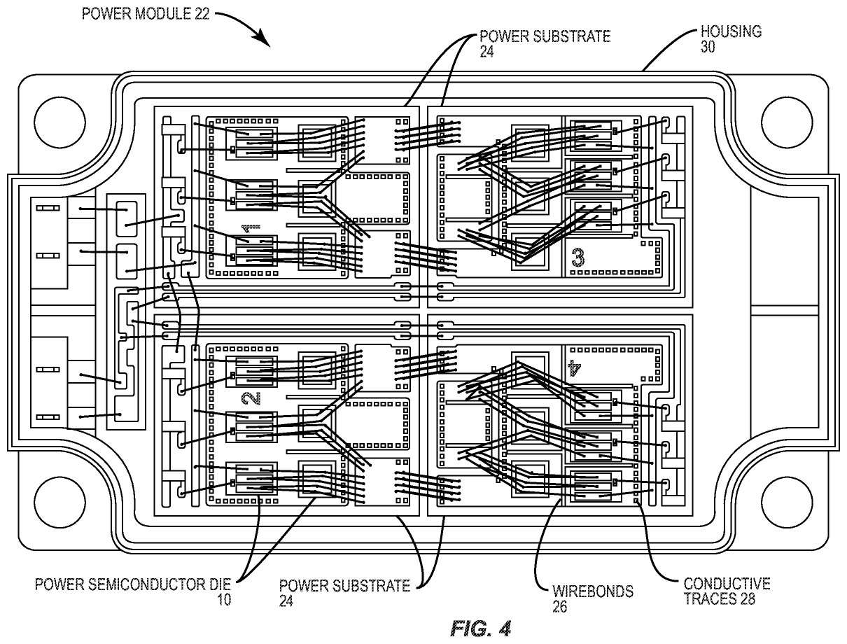

FIG. 4 illustrates a power module 22 according to one embodiment of the present disclosure. The power module 22 includes a number of power semiconductor die 10, each of which are mounted on a power substrate 24 and interconnected via a combination of conductive traces 28 and wirebonds 26 to provide a desired topology. A housing 30 includes the one or more power substrates 24.

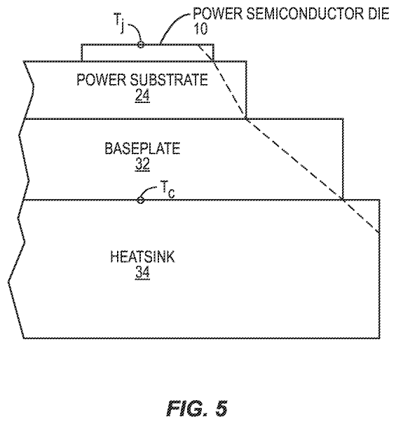

FIG. 5 illustrates a cross-sectional view of a single power semiconductor die 10 provided in a power module 22. The power substrate 24 is provided on a baseplate 32, which is in turn provided on a heatsink 34. Heat generated by the power semiconductor die 10 during operation thereof must dissipate from the die through the power substrate 24, the baseplate 32, and the heatsink 34. Generally, heat flows out of the power semiconductor die 10 and through the various parts of the stack in a trapezoidal pattern, which is shown as a dashed line. Conventionally designed power semiconductor die 10 in which the active area 12 is maximized and the total area is minimized create a bottleneck in the heat dissipation at the power semiconductor die 10 itself, such that the thermal resistance of the power semiconductor die 10 is a limiting factor in how much heat can be extracted therefrom. To prevent performance and/or longevity issues as a result of heat buildup, the power semiconductor die 10 must be throttled by reducing the operating voltage and/or current thereof as discussed above. By providing the thermal dissipation area 20, this bottleneck can be removed so that the power semiconductor die 10 can be operated at higher voltages and/or currents.

In particular, a relationship between the power dissipation and thermal resistance of the power semiconductor die 10 can be expressed according to Equation (1):

$${P}_{diss} = \frac{{T}_{diff ( j \to c )}}{{R}_{th}} \qquad ( 1 )$$

where P_{diss} is the allowed power dissipation for a given temperature differential between junction and case T_{diff(j→c)} and Rₜₕ is the thermal resistance between the power semiconductor die 10 and the heatsink 34. FIG. 5 shows the junction temperature Tⱼ and the case temperature T_{c}—the temperature differential between the junction and the case T_{diff(j→c)} is equal to T_{diff(j→c)}. Generally, the temperature differential between junction and case T_{diff(j→c)} is set according to a desired reliability for the power module 22. Accordingly, the power dissipation P_{diss} is limited by the thermal resistance Rₜₕ between the power semiconductor die 10 and the heatsink 34. The thermal dissipation area 20 lowers the thermal resistance Rₜₕ and thus allows increased power dissipation with the same temperature differential between junction and case T_{diff(j→c)}.

Notably, the view shown in FIG. 5 is merely exemplary. In various embodiments, the baseplate 32 may be removed (i.e., for a baseplate-less power module) or additional components may be present between the power semiconductor die 10 and the heatsink 34. The principles discussed above apply equally to any thermal stack in a power module 22.

As the blocking voltage of a power semiconductor die 10 increases, so does the area of the edge termination area 14 in proportion to the total area of the power semiconductor die 10. This is because higher blocking voltages generate higher electric fields, which require additional area to be reduced to a suitable level by the edge termination area 14. At a certain point, the edge termination area 14 for a given blocking voltage becomes large enough that it provides adequate thermal dissipation so that the power semiconductor die 10 is no longer a bottleneck in the thermal dissipation discussed above with respect to FIG. 4. Adding the thermal dissipation area 20 to power semiconductor die 10 of a certain size/blocking voltage thus becomes redundant for thermal purposes, but may still increase yield as discussed above. Accordingly, in various embodiments the blocking voltage of the power semiconductor die 10 may be less than 10 kV, less than 9 kV, less than 8 kV, less than 7 kV, and less than 6.5 kV. Below these exemplary blocking voltages, the thermal resistance of the power semiconductor die 10 remains a bottleneck in the power dissipation as discussed above. In other words, the principles of the present disclosure may be especially beneficial when applied to power semiconductor die 10 having a total area less than 50 mm², less than 45 mm², less than 40 mm², and less than 35 mm² in various embodiments.

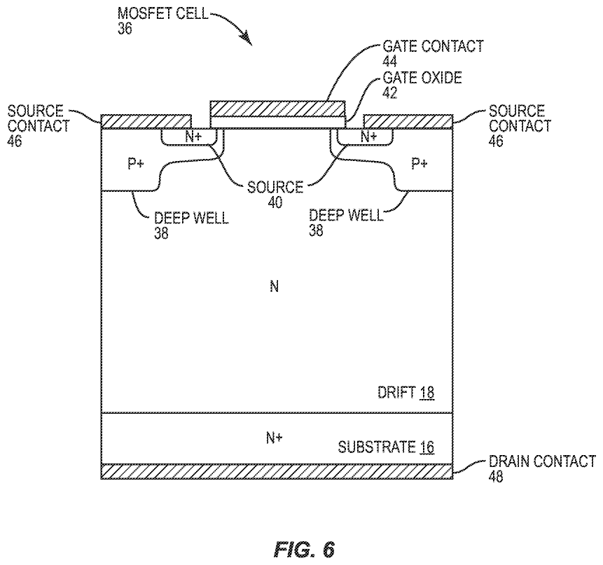

As discussed above, the active area 12 includes one or more implanted regions configured to provide the functionality of the device. In particular, the active area 12 includes one or more implanted regions configured to selectively deliver current between two contacts. FIG. 6 thus shows a cross-sectional view of a MOSFET cell 36 according to one embodiment of the present disclosure. The MOSFET cell 36 is formed in the active area 12 of the power semiconductor die 10 and includes a number of deep well regions 38 and a number of source regions 40 within the deep well regions 38. A gate oxide 42 electrically contacts each source region 40 and each deep well region 38. A gate contact 44 is on the gate oxide 42. A number of source contacts 46 contact a source region 40 and a deep well region 38. A drain contact 48 electrically contacts the substrate 16 on the backside of the device. In operation, a voltage at the gate contact 44 controls the amount of current allowed to flow between the drain contact 48 and the source contacts 46. The MOSFET cell 36 may be tiled throughout the active area 12 of the power semiconductor device 10 any number of times to provide a MOSFET having a desired current carrying capacity and blocking voltage capability. While not shown, the active region could similarly contain implanted regions configured to provide an IGBT, a diode, or any other power semiconductor device.

Those skilled in the art will recognize improvements and modifications to the preferred embodiments of the present disclosure. All such improvements and modifications are considered within the scope of the concepts disclosed herein and the claims that follow.

What is claimed is:

1. A power semiconductor die comprising:
a substrate; and
a drift layer on the substrate, the drift layer comprising:
an active area;
an edge termination area surrounding the active area; and
a thermal dissipation area surrounding the edge termination area and configured to reduce a thermal resistance of the power semiconductor die.

2. The power semiconductor die of claim 1 wherein:
the active area comprises one or more implanted regions and is configured to conduct current during a conduction mode of operation of the power semiconductor die;
the edge termination area comprises one or more implanted termination regions and is configured to reduce an electric field during a blocking mode of operation of the power semiconductor die; and
the thermal dissipation area is electrically inactive.

3. The power semiconductor die of claim 2 wherein the thermal dissipation area does not include any implanted regions.

4. The power semiconductor die of claim 2 wherein a ratio of the combination of the active area and the edge termination area to the combination of the active area, the edge termination area, and the thermal dissipation area is between 1:1.10 and 1:1.35.

5. The power semiconductor die of claim 2 wherein the thermal dissipation area comprises at least 10% of a total area of the power semiconductor die and less than 35% of the total area of the power semiconductor die.

6. The power semiconductor die of claim 2 wherein a blocking voltage of the power semiconductor die is less than 10 kV.

7. The power semiconductor die of claim 2 wherein the substrate and the drift layer comprise a wide bandgap semiconductor material.

8. The power semiconductor die of claim 7 wherein the wide bandgap semiconductor material comprises silicon carbide.

9. The power semiconductor die of claim 2 wherein the one or more implanted regions in the active area provide a metal-oxide-semiconductor field-effect transistor (MOSFET).

10. A power semiconductor die comprising:
a substrate;
a drift layer on the substrate, the drift layer comprising an active area and an edge termination area, wherein the combination of the active area and the edge termination area comprises less than 90% of a total area of the power semiconductor die, and as low as 65% of the total area of the power semiconductor die.

11. The power semiconductor die of claim 10 wherein:
the active area comprises one or more implanted regions and is configured to conduct current during a conduction mode of operation of the power semiconductor die; and
the edge termination area comprises one or more implanted termination regions and is configured to reduce an electric field during a blocking mode of operation of the power semiconductor die.

12. The power semiconductor die of claim 11 wherein the substrate and the drift layer comprise a wide bandgap semiconductor material.

13. The power semiconductor die of claim 11 wherein the wide bandgap semiconductor material comprises silicon carbide.

14. The power semiconductor die of claim 11 wherein a blocking voltage of the power semiconductor device is less than 10 kV.

15. The power semiconductor die of claim 11 wherein the one or more implanted regions in the active area provide a metal-oxide-semiconductor field-effect transistor (MOSFET).

16. A power module comprising:
a power substrate;
one or more power semiconductor die on the power substrate, each of the one or more power semiconductor die comprising:
a substrate; and
a drift layer on the substrate, the drift layer comprising:
an active area;
an edge termination area surrounding the active area; and
a thermal dissipation area surrounding the edge termination area and configured to reduce a thermal resistance of the power semiconductor die.

17. The power module of claim 16 wherein for each of the one or more power semiconductor die:
the active area comprises one or more implanted regions and is configured to conduct current during a conduction mode of operation of the power semiconductor die;
the edge termination area comprises one or more implanted termination regions and is configured to reduce an electric field during a blocking mode of operation of the power semiconductor die; and
the thermal dissipation area is electrically inactive.

18. The power module of claim 16 wherein for each of the one or more power semiconductor die, a ratio of the combination of the active area and the edge termination area to the combination of the active area, the edge termination area, and the thermal dissipation area is between 1:1.10 and 1:1.35.

19. The power module of claim 16 wherein for each of the one or more power semiconductor die, the thermal dissipation area comprises at least 10% of a total area of the power semiconductor die, and up to 35% of the total area of the power semiconductor die.

20. The power module of claim 16 wherein a blocking voltage of each of the one or more power semiconductor die is less than 10 kV.
